(19) United States
(12) Patent Application Publication
(10) Pub. No.: US 2021/0132488 A1
(43) Pub. Date: May 6, 2021

(54) MASK BLANK, PHASE-SHIFT MASK, AND SEMICONDUCTOR DEVICE MANUFACTURING METHOD

(71) Applicant: HOYA CORPORATION, Tokyo (JP)

(72) Inventors: Hiroaki SHISHIDO, Tokyo (JP); Hitoshi MAEDA, Tokyo (JP); Masahiro HASHIMOTO, Tokyo (JP)

(73) Assignee: HOYA CORPORATION, Tokyo (JP)

(21) Appl. No.: 17/058,591

(22) PCT Filed: May 8, 2019
(86) PCT No.: PCT/JP2019/018386

§ 371 Date: Nov. 24, 2020

(30) Foreign Application Priority Data
May 30, 2018 (JP) 2018-103475

(51) Int. Cl. G03F 1/32; H01L 21/027

(52) U.S. Cl. CPC G03F 1/32; H01L 21/0274

(57) ABSTRACT

Provided is a mask blank including a phase shift film The phase shift film has a structure where a first layer, a second layer, and a third layer are stacked in this order from a side of the transparent substrate. Refractive indexes n₁, n₂, and n₃ of the first layer, the second layer, and the third layer, respectively, at a wavelength of an exposure light of an ArF excimer laser satisfy the relations n₁>n₂ and n₂<n₃. Extinction coefficients k₁, k₂, and k₃ of the first layer, the second layer, and the third layer, respectively, at a wavelength of the exposure light satisfy the relations k₁<k₂ and k₂>k₃. Film thicknesses d₁, d₂, and d₃ of the first layer, the second layer, and the third layer, respectively, satisfy the relations d₁<d₃ and d₂<d₃.

### CROSS-REFERENCE TO RELATED APPLICATIONS

This application is a National Stage of International Application No. PCT/US2019/018386, filed May 8, 2019, which claims priority to Japanese Patent Application No. 2018-103475, filed May 30, 2018, and the contents of which is incorporated by reference.

### TECHNICAL FIELD

This disclosure relates to a mask blank and a phase shift mask manufactured using the mask blank. This disclosure further relates to a method of manufacturing a semiconductor device using the phase shift mask.

### BACKGROUND ART

Generally, in a manufacturing process of a semiconductor device, photolithography is used to form a fine pattern. Multiple substrates called transfer masks are usually utilized in forming the fine pattern. In order to miniaturize a pattern of a semiconductor device, in addition to miniaturization of a mask pattern formed in a transfer mask, it is necessary to shorten a wavelength of an exposure light source used in photolithography. Shortening of wavelength has been advancing recently from the use of a KrF excimer laser (wavelength 248 nm) to an ArF excimer laser (wavelength 193 nm) as an exposure light source in the manufacture of a semiconductor device.

As for the types of transfer masks, a half tone phase shift mask is known in addition to a conventional binary mask having a light shielding pattern formed from a chromium-based material on a transparent substrate.

Patent Document 1 discloses a binary mask blank including a light shielding film and front and back surface anti-reflection films. Patent Document 1 includes a back surface anti-reflection film formed in contact below a light shielding film and which includes silicon, a transition metal, oxygen, and nitrogen, and in which a refractive index n₂ of the film is 1.0-3.5, an extinction coefficient k₂ of the film is 2.5 or less, and film thickness t2 is 5-40 nm for suppressing flare affecting adjacent shots caused by a reflection from a light shielding band, and dose error in a pattern area. Patent Document 1 achieves a binary mask blank having a reflectance to an entrance of a light from a transparent substrate side (hereinafter referred to as back surface reflectance) of about 30% or less, specifically, about 29% or about 23% as shown in the examples.

Patent Document 2 discloses a half tone phase shift mask blank provided with a phase shift film on a transparent substrate, which has a function to transmit an ArF exposure light at a predetermined transmittance and to generate a predetermined amount of phase shift to the transmitting ArF exposure light. The phase shift film of Patent Document 2 has a stacked structure including a high transmission layer and a low transmission layer. Further, a SiN-based film having a relatively high nitrogen content is applied to the high transmission layer, and a SiN-based film having a relatively low nitrogen content is applied to the low transmission layer.

Recently, an illumination system used for an exposure-transfer on a resist film on a semiconductor device is showing increased advancement and complication. Patent Document 3 discloses a method for configuring an illumination source of a lithographic apparatus to enhance imaging of a mask pattern onto a substrate. The method includes six steps: (1) Dividing the illumination source into pixel groups, each pixel group including one or more illumination source points in a pupil plane of the illumination source. (2) Changing a polarization state of each pixel group and determining an incremental effect on each of the plurality of critical dimensions resulting from the change of polarization state of each pixel group. (3) Calculating a first plurality of sensitivity coefficients for each of the plurality of critical dimensions using the determined incremental effects. (4) Selecting an initial illumination source. (5) Iteratively calculating a lithographic metric as a result of a change of polarization state of a pixel group in the initial illumination source using the calculated first plurality of sensitivity coefficients, the change of the polarization state of the pixel group in the initial illumination source creating a modified illumination source. (6) Adjusting the initial illumination source based on the iterative results of calculations.

### PRIOR ART PUBLICATIONS

### Patent Documents

### Patent Document 1

Japanese Patent No. 5054766

### Patent Document 2

Japanese Patent Application Publication 2014-137388

### Patent Document 3

Japanese Patent Application Publication 2012-74695

### SUMMARY OF THE DISCLOSURE

### Problems to be Solved by the Disclosure

Recently, there are demands for further miniaturization of transfer patterns, and an illumination system used in exposure transfer is also showing increased advancement and complication. For example, the illumination system of Patent Document 3 is controlled to optimize the position and angle of an illumination source. In the case of exposing a transfer mask with an exposure light of an ArF excimer laser with a relatively short wavelength in such a complicated illumination system, a stray light is likely to generate, which is caused by multiple reflections in a transparent substrate of the transfer mask. The stray light reaching bar codes and alignment marks provided outside of a pattern forming region of a transparent substrate of a transfer mask in exposure-transferring a resist film on a semiconductor device causes the bar codes and alignment marks to be projected onto the resist film on the semiconductor device. This phenomenon causes CD variations on the resist film of the semiconductor device. Since bar codes and alignment marks formed on a thin film on a transparent substrate are essential for identification and registration of transfer masks, their removal is not realistic. Further, an illumination system used for an exposure transfer is generally provided with a shutter mechanism to block an external area of an exposure region of a transfer mask from being irradiated by an exposure light. However, due to increasing oblique incidence components of an exposure light by the aforementioned optimization of position and angle of an illumination source, it is difficult to suppress a stray light caused by multiple reflections of an exposure light irradiated into an exposure region of a transfer mask onto an external area of an exposure region in a transparent substrate. Due to such a circumstance, it is becoming difficult to satisfy further demand of miniaturization of a transfer pattern in a mask blank having a back surface reflectance of about 30%, which was conventionally accepted.

This disclosure was made to solve a conventional problem. An aspect of the disclosure is to provide a mask blank having a phase shift film on a transparent substrate, the phase shift film having both of a function to transmit an exposure light of an ArF excimer laser at a predetermined transmittance and a function to generate a predetermined phase difference to the transmitting exposure light of the ArF excimer laser, the phase shift film further having a reduced back surface reflectance. A further aspect is to provide a phase shift mask manufactured using this mask blank. Yet another aspect of this disclosure is to provide a method of manufacturing a semiconductor device using such a phase shift mask.

### Means for Solving the Problem

For achieving the above aspects, this disclosure includes the following configurations.

### (Configuration 1)

A mask blank including a phase shift film on a transparent substrate,

in which the phase shift film has a structure where a first layer, a second layer, and a third layer are stacked in this order from a side of the transparent substrate,

in which refractive indexes n₁, n₂, and n₃ of the first layer, the second layer, and the third layer, respectively, at a wavelength of an exposure light of an ArF excimer laser satisfy relations of n₁>n₂ and n₂<n₃,

in which extinction coefficients k₁, k₂, and k₃ of the first layer, the second layer, and the third layer, respectively, at a wavelength of the exposure light satisfy relations of k₁<k₂ and k₂>k₃, and

in which film thicknesses d₁, d₂, and d₃ of the first layer, the second layer, and the third layer, respectively, satisfy relations of d₁<d₃ and d₂<d₃.

### (Configuration 2)

The mask blank according to Configuration 1, in which a film thickness d₃ of the third layer is two times or more than a film thickness d₁ of the first layer.

### (Configuration 3)

The mask blank according to Configuration 1 or 2, in which a film thickness d₂ of the second layer is 20 nm or less.

### (Configuration 4)

The mask blank according to any of Configurations 1 to 3, in which a refractive index n₁ of the first layer is 2.0 or more, an extinction coefficient k₁ of the first layer is 0.5 or less, a refractive index n₂ of the second layer is less than 2.0, an extinction coefficient k₂ of the second layer is 1.0 or more, a refractive index n₃ of the third layer is 2.0 or more, and an extinction coefficient k₃ of the third layer is 0.5 or less.

### (Configuration 5)

The mask blank according to any of Configurations 1 to 4, in which the phase shift film has a function to transmit the exposure light at a transmittance of 2% or more, and a function to generate a phase difference of 150 degrees or more and 200 degrees or less between the exposure light transmitted through the phase shift film and the exposure light transmitted through the air for a same distance as a thickness of the phase shift film.

### (Configuration 6)

The mask blank according to any of Configurations 1 to 5, in which the first layer is provided in contact with a surface of the transparent substrate.

### (Configuration 7)

The mask blank according to any of Configurations 1 to 6, in which the first layer, the second layer, and the third layer are formed from a material including silicon and nitrogen, or a material including silicon, nitrogen, and one or more elements selected from a metalloid element and a non-metallic element.

### (Configuration 8)

The mask blank according to Configuration 7, in which a nitrogen content of the second layer is less than a nitrogen content of both of the first layer and the third layer.

### (Configuration 9)

The mask blank according to any of Configurations 1 to 8,

in which the phase shift film includes a fourth layer on the third layer,

in which a refractive index n₄ of the fourth layer at a wavelength of the exposure light satisfies relations of n₁>n₄ and n₃>n₄, and

in which an extinction coefficient k₄ of the fourth layer at a wavelength of the exposure light satisfies relations of k₁>k₄ and k₃>k₄.

### (Configuration 10)

The mask blank according to Configuration 9, in which a refractive index n₄ of the fourth layer is 1.8 or less and an extinction coefficient k₄ of the fourth layer is 0.1 or less.

### (Configuration 11)

The mask blank according to Configuration 9 or 10, in which the fourth layer is formed from a material including silicon and oxygen, or a material including silicon, oxygen, and one or more elements selected from a metalloid element and a non-metallic element.

### (Configuration 12)

A phase shift mask including a phase shift film having a transfer pattern on a transparent substrate,

in which the phase shift film has a structure where a first layer, a second layer, and a third layer are stacked in this order from a side of the transparent substrate,

in which refractive indexes n₁, n₂, and n₃ of the first layer, the second layer, and the third layer, respectively, at a wavelength of an exposure light of an ArF excimer laser satisfy relations of n₁>n₂ and n₂<n₃,

in which extinction coefficients k₁, k₂, and k₃ of the first layer, the second layer, and the third layer, respectively, at a wavelength of the exposure light satisfy relations of k₁<k₂ and k₂>k₃, and

in which film thicknesses d₁, d₂, and d₃ of the first layer, the second layer, and the third layer, respectively, satisfy relations of d₁<d₃ and d₂<d₃.

### (Configuration 13)

The phase shift mask according to Configuration 12, in which a film thickness d₃ of the third layer is two times or more than a film thickness d₁ of the first layer.

### (Configuration 14)

The phase shift mask according to Configuration 12 or 13, in which a film thickness d₂ of the second layer is 20 nm or less.

### (Configuration 15)

The phase shift mask according to any of Configurations 12 to 14, in which a refractive index n₁ of the first layer is 2.0 or more, an extinction coefficient k₁ of the first layer is 0.5 or less, a refractive index n₂ of the second layer is less than 2.0, an extinction coefficient k₂ of the second layer is 1.0 or more, a refractive index n₃ of the third layer is 2.0 or more, and an extinction coefficient k₃ of the third layer is 0.5 or less.

### (Configuration 16)

A phase shift mask according to any of Configurations 12 to 15, in which the phase shift film has a function to transmit the exposure light at a transmittance of 2% or more, and a function to generate a phase difference of 150 degrees or more and 200 degrees or less between the exposure light transmitted through the phase shift film and the exposure light transmitted through the air for a same distance as a thickness of the phase shift film.

### (Configuration 17)

The phase shift mask according to any of Configurations 12 to 16, in which the first layer is provided in contact with a surface of the transparent substrate.

### (Configuration 18)

The phase shift mask according to any of Configurations 12 to 17, in which the first layer, the second layer, and the third layer are formed from a material including silicon and nitrogen, or a material including silicon, nitrogen, and one or more elements selected from a metalloid element and a non-metallic element.

### (Configuration 19)

The phase shift mask according to Configuration 18, in which a nitrogen content of the second layer is less than a nitrogen content of both of the first layer and the third layer.

### (Configuration 20)

The phase shift mask according to any of Configurations 12 to 19,

in which the phase shift film includes a fourth layer on the third layer,

in which a refractive index n₄ of the fourth layer at a wavelength of the exposure light satisfies relations of n₁>n₄ and n₃>n₄, and
in which an extinction coefficient k₄ of the fourth layer at a wavelength of the exposure light satisfies relations of k₁>k₄ and k₃>k₄.

### (Configuration 21)

The phase shift mask according to Configuration 20, in which a refractive index n₄ of the fourth layer is 1.8 or less and an extinction coefficient k₄ of the fourth layer is 0.1 or less.

### (Configuration 22)

The phase shift mask according to Configuration 20 or 21, in which the fourth layer is formed from a material including silicon and oxygen, or a material including silicon, oxygen, and one or more elements selected from a metalloid element and a non-metallic element.

### (Configuration 23)

A method of manufacturing a semiconductor device including the step of using the phase shift mask according to any of Configurations 12 to 22 and exposure-transferring a transfer pattern on a resist film on a semiconductor substrate.

### Effect of the Disclosure

Provided in this disclosure is a mask blank including a phase shift film on a transparent substrate, the phase shift film having both of a function of transmitting an exposure light of an ArF excimer laser at a predetermined transmittance and a function of generating a predetermined phase difference to the transmitting exposure light of an ArF excimer laser, and in which the phase shift film has a reduced back surface reflectance.

### BRIEF DESCRIPTION OF THE DRAWINGS

FIG. 1 is a cross-sectional view showing a configuration of the mask blank of the first embodiment of this disclosure.

FIG. 2 is a cross-sectional view showing a configuration of the mask blank of the second embodiment of this disclosure.

FIGS. 3A-3G are schematic cross-sectional views showing a manufacturing process of the phase shift mask according to the first and second embodiments of this disclosure.

### EMBODIMENTS FOR CARRYING OUT THE DISCLOSURE

The embodiments of this disclosure are explained below. The inventors of this application diligently studied a phase shift film regarding means that can further reduce a back surface reflectance, while having both of a function to transmit an exposure light of an ArF excimer laser (hereafter simply referred to as an exposure light) at a predetermined transmittance and a function to generate a predetermined phase difference.

A stray light that generates upon an exposure on a transfer mask is considered as caused by a light in which a part of an exposure light entered from a surface (back surface) of a back side (side without a phase shift film) of a transparent substrate of a phase shift mask is reflected at an interface between the transparent substrate and the phase shift film, further reflected again at an interface between the back surface of the transparent substrate and the air, and exited from a region without the phase shift film on a surface of the front side of the transparent substrate. To suppress the projection of bar codes and alignment marks that generates by the stray light, a light intensity of the stray light to a light intensity of the exposure light that is irradiated on the transparent substrate is preferably 0.2% or less. In a phase shift mask, a light shielding band (stacked structure of a phase shift film and a light shielding film) provided on a peripheral region of a region at which a transfer pattern is formed is considered as preferably having a transmittance of 0.2% or less. With such a transmittance, it is considered that there is substantially no influence of a transmitting exposure light on CD variation of a resist film on a semiconductor device.

In exposing a phase shift mask with an exposure light of an ArF excimer laser, upon the exposure light entering a back surface of a transparent substrate from the air, a light that reflects on the back surface of the transparent substrate generates, which is about 5% of the entering light (i.e., light intensity of the exposure light entering the interior of the transparent substrate is reduced by about 5%). Further, when a part of an exposure light reflected at an interface between a transparent substrate and a phase shift film is reflected at an interface between a back surface of the transparent substrate and the air, the part of the light is not reflected and exits from the back surface. As a result of examining these points, the inventors reached an idea that in the state where only a phase shift film exists on a transparent substrate, a reflectance (back surface reflectance) at the transparent substrate side (back surface side) to an exposure light of 9% or less can make a light intensity of a stray light 0.2% or less, and can suppress projection of bar codes and alignment marks.

Incidentally, in actually measuring a back surface reflectance of a phase shift film, a measuring light is irradiated on a transparent substrate on a surface that is opposite to the side to which a phase shift film is provided (back surface), a light intensity of the reflected light is measured, and a back surface reflectance is calculated from the light intensity of the reflected light. The light intensity of the measured reflected light is the light intensity of a light including at least a light reflected at an interface between the air and the transparent substrate, and a light in which the measurement light that was not reflected at the interface and entered the transparent substrate is reflected at an interface between the transparent substrate and the phase shift film, and further exited into the air without being reflected again at an interface between the back surface of the transparent substrate and the air (light slightly less than 4% of the light entered the interface). Namely, the back surface reflectance of 9% or less is a back surface reflectance that is calculated by a light including reflected lights other than the light reflected at the interface between the transparent substrate and the phase shift film.

The inventors of this application studied a configuration of a mask blank including a phase shift film for achieving a back surface reflectance of 9% or less, while having both of a function to transmit an exposure light of an ArF excimer laser at a predetermined transmittance and a function to generate a predetermined phase difference.

A material for forming a conventional phase shift film preferably has a refractive index n as large as possible, and an extinction coefficient k within a scope that is not too large and not too small. This is because the major design concept of the conventional phase shift film is to transmit an exposure light of an ArF excimer laser at a predetermined transmittance by absorbing the exposure light of an ArF excimer laser inside of the phase shift film, while generating a predetermined phase difference to the transmitting exposure light of an ArF excimer laser. In a phase shift film of a single layer structure, it is difficult to achieve a back surface reflectance of 9% or less while having a function required for the phase shift film (function to generate a predetermined transmittance and phase difference to an exposure light of an ArF excimer laser that transmits through the phase shift film). Thus, the inventors of this application studied constructing a phase shift film from a plurality of layers and achieving, throughout the layers as a whole, a back surface reflectance of 9% or less, while having both of a function to transmit an exposure light of an ArF excimer laser at a predetermined transmittance and a function to generate a predetermined phase difference. To reduce a back surface reflectance of a phase shift film to an exposure light of an ArF excimer laser, it is necessary to utilize an interference effect of a reflected light at an interface between the transparent substrate and the phase shift film, and a reflected light at an interface between the layers constructing the phase shift film.

As a result of considering these points, the inventors found out that a phase shift film achieving a back surface reflectance of 9% or less while having a predetermined transmittance and predetermined phase difference to an exposure light of an ArF excimer laser can be formed by constructing a phase shift film from a first layer, a second layer, and a third layer stacked in this order from a transparent substrate side, and adjusting refractive indexes n₁, n₂, n₃, extinction coefficients k₁, k₂, k₃, and film thicknesses d₁, d₂, d₃ of the first layer, the second layer, and the third layer at a wavelength of an exposure light of an ArF excimer laser. This disclosure was made as a result of the diligent studies described above.

FIG. 1 is a cross-sectional view showing a configuration of a mask blank 100 of the first embodiment of this disclosure. The mask blank 100 of this disclosure shown in FIG. 1 has a structure where a phase shift film 2, a light shielding film 3, and a hard mask film 4 are stacked in this order on a transparent substrate 1.

The transparent substrate 1 can be made of quartz glass, aluminosilicate glass, soda-lime glass, low thermal expansion glass (Si0₂—TiO₂ glass, etc.), etc., in addition to synthetic quartz glass. Among the above, synthetic quartz glass is particularly preferable as a material for forming the transparent substrate 1 of the mask blank for having a high transmittance to an ArF excimer laser light. A refractive index n of the material forming the transparent substrate 1 to an exposure light wavelength (about 193 nm) of an ArF excimer laser is preferably 1.5 or more and 1.6 or less, more preferably 1.52 or more and 1.59 or less, and even more preferably 1.54 or more and 1.58 or less.

To generate a sufficient phase shift effect between the exposure light transmitted through the interior of the phase shift film 2 and the exposure light transmitted through the air, the phase shift film 2 preferably has a transmittance to an exposure light of an ArF excimer laser of 2% or more. A transmittance of the phase shift film 2 to an exposure light is preferably 3% or more, and more preferably 4% or more. On the other hand, a transmittance of the phase shift film 2 to an exposure light is preferably 15% or less, and more preferably 14% or less.

To obtain a proper phase shift effect, it is desirable for the phase shift film 2 to be adjusted such that a phase difference that generates between the transmitting exposure light of an ArF excimer laser and the light that transmitted through the air for the same distance as a thickness of the phase shift film 2 is within the range of 150 degrees or more and 200 degrees or less. The lower limit of the phase difference of the phase shift film 2 is preferably 155 degrees or more, and more preferably 160 degrees or more. On the other hand, the upper limit of the phase difference in the phase shift film 2 is preferably 190 degrees or less.

It is preferable that the phase shift film 2 in the state where only the phase shift film 2 is present on the transparent substrate 1 has at least 9% or less back surface reflectance to an exposure light of an ArF excimer laser.

The phase shift film 2 has a structure where a first layer 21, a second layer 22, and a third layer 23 are stacked from the transparent substrate 1 side. It is required to at least satisfy each condition of the transmittance, the phase difference, and the back surface reflectance given above in the entire phase shift film 2. The inventors found out that for the phase shift film 2 to satisfy the above conditions, it is necessary that refractive indexes n₁, n₂, n₃ of the first layer 21, the second layer 22, and the third layer 23, respectively, to a wavelength of an exposure light of an ArF excimer laser satisfy the relations of n₁>n₂ and n₂<n₃, and extinction coefficients k₁, k₂, k₃ of the first layer 21, the second layer 22, and the third layer 23, respectively, to a wavelength of an exposure light of an ArF excimer laser satisfy the relations of k₁<k₂ and k₂>k₃.

In addition to the above, a refractive index n₁ of the first layer 21 is preferably 2.0 or more, and more preferably 2.1 or more. Further, a refractive index n₁ of the first layer 21 is preferably 3.0 or less, and more preferably 2.8 or less. An extinction coefficient k₁ of the first layer 21 is preferably 0.5 or less, and more preferably 0.4 or less. Further, an extinction coefficient k₁ of the first layer 21 is preferably 0.1 or more, and more preferably 0.2 or more. A refractive index n₁ and an extinction coefficient k₁ of the first layer 21 are values derived by regarding the entire first layer 21 as a single, optically uniform layer.

For the phase shift film 2 to satisfy the above conditions, a refractive index n₂ of the second layer 22 is preferably less than 2.0, and more preferably 1.9 or less. Further, a refractive index n₂ of the second layer 22 is preferably 1.0 or more, and more preferably 1.2 or more. Further, an extinction coefficient k₂ of the second layer 22 is preferably 1.0 or more, and more preferably 1.2 or more. Further, an extinction coefficient k₂ of the second layer 22 is preferably 2.2 or less, and more preferably 2.0 or less. A refractive index n₂ and an extinction coefficient k₂ of the second layer 22 are values derived by regarding the entire second layer 22 as a single, optically uniform layer.

For the phase shift film 2 to satisfy the above conditions, a refractive index n₃ of the third layer 23 is preferably 2.0 or more, and more preferably 2.1 or more. Further, a refractive index n₃ of the third layer 23 is preferably 3.0 or less, and more preferably 2.8 or less. An extinction coefficient k₃ of the third layer 23 is preferably 0.5 or less, and more preferably 0.4 or less. Further, an extinction coefficient k₃ of the third layer 23 is preferably 0.1 or more, and more preferably 0.2 or more. A refractive index n₃ and an extinction coefficient k₃ of the third layer 23 are values derived by regarding the entire third layer 23 as a single, optically uniform layer.

A refractive index n and an extinction coefficient k of a thin film including the phase shift film 2 are not determined only by the composition of the thin film. Film density and crystal condition of the thin film are also the factors that affect a refractive index n and an extinction coefficient k. Therefore, the conditions in forming a thin film by reactive sputtering are adjusted so that the thin film reaches desired refractive index n and extinction coefficient k. For allowing the first layer 21, the second layer 22, and the third layer 23 to have refractive indexes n and extinction coefficients k of the above range, not only the ratio of mixed gas of noble gas and reactive gas (oxygen gas, nitrogen gas, etc.) is adjusted in forming the film by reactive sputtering, but various other adjustments are made upon forming the film by reactive sputtering, such as pressure in a film forming chamber, power applied to the sputtering target, and positional relationship such as distance between the target and the transparent substrate 1. Further, these film forming conditions are specific to film forming apparatuses, and are adjusted arbitrarily for the first layer 21, the second layer 22, and the third layer 23 to be formed to achieve desired refractive index n and extinction coefficient k.

For the phase shift film 2 to satisfy the above conditions, it is at least necessary that, in addition to the optical properties of the first layer 21, the second layer 22, and the third layer 23, film thicknesses d₁, d₂, d₃ of the first layer 21, the second layer 22, and the third layer 23, respectively, satisfy relations of d₁<d₃ and d₂<d₃.

The thickness of the first layer 21 is preferably 20 nm or less, and more preferably 18 nm or less. Further, the thickness of the first layer 21 is preferably 3 nm or more, and more preferably 5 nm or more.

The thickness of the second layer 22 is preferably 20 nm or less, and more preferably 18 nm or less. Further, the thickness of the second layer 22 is preferably 2 nm or more, and more preferably 3 nm or more.

The first layer 21 contributes to adjustment of a back surface reflectance of the phase shift film 2 more than the two other layers. Further, the second layer 22 contributes to adjustment of a transmittance of the phase shift film 2 more than the two other layers. Therefore, degree of design freedom of film thickness of the first layer 21 and the second layer 22 is relatively small. The third layer 23 is required to contribute to adjustment for having a predetermined phase difference required for the phase shift film 2, and preferably has a greater film thickness than the two other layers. A film thickness d₃ of the third layer 23 is preferably two times or more than a film thickness d₁ of the first layer 21, more preferably 2.2 times or more, and even more preferably 2.5 times or more. Further, a film thickness d₃ of the third layer 23 is preferably five times or less than a film thickness d₁ of the first layer 21. The thickness of the third layer 23 is preferably 60 nm or less, and more preferably 50 nm or less. Further, the thickness of the third layer 23 is preferably more than 20 nm, and more preferably 25 nm or more.

The first layer 21, the second layer 22, and the third layer 23 are preferably formed from a material including silicon and nitrogen, or a material formed from silicon, nitrogen, and one or more elements selected from metalloid elements and non-metallic elements. Among these metalloid elements, it is preferable to include one or more elements selected from boron, germanium, antimony, and tellurium, since enhancement in conductivity of silicon to be used as a sputtering target can be expected. Among these non-metallic elements, it is preferable to include one or more elements selected from nitrogen, carbon, fluorine, and hydrogen. These non-metallic elements include noble gas such as helium (He), argon (Ar), krypton (Kr), and xenon (Xe).

The second layer 22 preferably has less nitrogen content than any of the first layer 21 and the third layer 23. A nitrogen content of the material forming the second layer 22 is preferably 40 atom % or less, and more preferably 35 atom % or less. The second layer 22 has to contribute to a transmittance of the phase shift film 2, and increasing a nitrogen content causes elevation of a transmittance. The first layer 21 and the third layer 23 are preferably 50 atom % or more, more preferably 55 atom % or more, and even more preferably constructed from Si₃N₄ which is a stoichiometrically stable material. The first layer and the third layer are preferably formed from a material having a high refractive index, since increasing a nitrogen content can increase a refractive index.

The first layer 21 is preferably formed in contact with a surface of the transparent substrate 1. This is because a configuration where the first layer 21 contacts the surface of the transparent substrate 1 can obtain greater effect of reducing a back surface reflectance that is generated by the stacked structure of the first layer 21, the second layer 22, and the third layer 23 of the phase shift film 2. If only slight influence is given on the effect of reducing a back surface reflectance of the phase shift film 2, an etching stopper film can be provided between the transparent substrate 1 and the phase shift film 2. In this case, the thickness of the etching stopper film needs to be 10 nm or less; and more preferably 7 nm or less, and even more preferably 5 nm or less. On the viewpoint of an effective function as an etching stopper, the thickness of the etching stopper film needs to be 3 nm or more. An extinction coefficient k of a material forming the etching stopper film should be less than 0.1, preferably 0.05 or less, and more preferably 0.01 or less. Further, a refractive index n of a material forming the etching stopper film in this case should at least be 1.9 or less, and preferably 1.7 or less. A refractive index n of a material forming the etching stopper film is preferably 1.55 or more. Further, the etching stopper film is preferably formed from a material containing silicon, aluminum, and oxygen.

It is preferable that the material forming the first layer 21 and the second layer 22, and the material forming the third layer 23 excluding the oxidized surface layer portion are both constructed of the same elements. The first layer 21, the second layer 22, and the third layer 23 are patterned by dry etching using the same etching gas. Therefore, the first layer 21, the second layer 22, and the third layer 23 are preferably etched in a same etching chamber. When the same elements are included in each material forming the first layer 21, the second layer 22, and the third layer 23, environmental change in the etching chamber can be reduced as the object to be dry-etched changes from the first layer 21, the second layer 22, and to the third layer 23.

While the first layer 21, the second layer 22, and the third layer 23 of the phase shift film 2 are formed through sputtering, any sputtering including DC sputtering, RF sputtering, ion beam sputtering, etc. is applicable. Application of DC sputtering is preferable, considering the film forming rate. In the case where the target has low conductivity, while application of RF sputtering and ion beam sputtering is preferable, application of RF sputtering is more preferable considering the film forming rate.

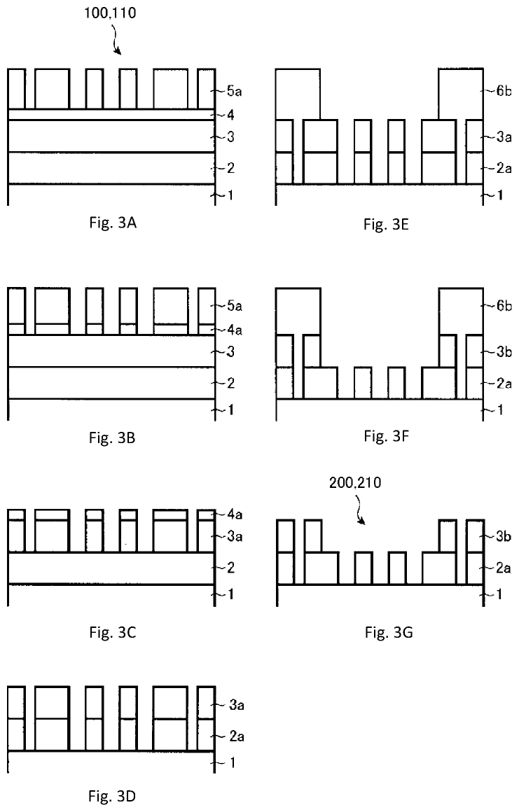

The mask blank 100 has a light shielding film 3 on the phase shift film 2. Generally, in a binary mask, an outer peripheral region of a region where a transfer pattern is formed (transfer pattern forming region) is desired to ensure an optical density (OD) of a predetermined value or more to prevent the resist film from being subjected to an influence of an exposure light that transmitted through the outer peripheral region when an exposure transfer was made on a resist film on a semiconductor wafer using an exposure apparatus. This point is similar in the case of a phase shift mask. Generally, the outer peripheral region of a transfer mask including a phase shift mask preferably has OD of 2.7 or more. The phase shift film 2 has a function to transmit an exposure light at a predetermined transmittance, and it is difficult to ensure an optical density of a predetermined value with the phase shift film 2 alone. Therefore, it is necessary to stack the light shielding film 3 on the phase shift film 2 at the stage of manufacturing the mask blank 100 to ensure lacking optical density. With such a configuration of the mask blank 100, the phase shift mask 200 ensuring a predetermined value of optical density on the outer peripheral region can be manufactured by removing the light shielding film 3 of the region which uses the phase shift effect (basically transfer pattern forming region) during manufacture of the phase shift mask 200 (see FIGS. 3A-3G).

A single layer structure and a stacked structure of two or more layers are applicable to the light shielding film 3. Further, each layer in the light shielding film 3 of a single layer structure and the light shielding film 3 with a stacked structure of two or more layers may be configured by approximately the same composition in the thickness direction of the layer or the film, or with a composition gradient in the thickness direction of the layer.

The mask blank 100 of the embodiment shown in FIG. 1 is configured as a structure where the light shielding film 3 is stacked on the phase shift film 2 without an intervening film. For the light shielding film 3 of this configuration, it is necessary to apply a material having a sufficient etching selectivity to etching gas used in forming a pattern in the phase shift film 2. The light shielding film 3 in this case is preferably formed from a material containing chromium. Materials containing chromium for forming the light shielding film 3 can include, in addition to chromium metal, a material containing chromium and one or more elements selected from oxygen, nitrogen, carbon, boron, and fluorine.

While a chromium-based material is generally etched by mixed gas of chlorine-based gas and oxygen gas, an etching rate of the chromium metal to the etching gas is not as high. Considering enhancing an etching rate of mixed gas of chlorine-based gas and oxygen gas to etching gas, the material forming the light shielding film 3 preferably contains chromium and one or more elements selected from oxygen, nitrogen, carbon, boron, and fluorine. Further, one or more elements among molybdenum, indium, and tin can be included in the material containing chromium for forming the light shielding film 3. Including one or more elements among molybdenum, indium, and tin can increase an etching rate to mixed gas of chlorine-based gas and oxygen gas.

The light shielding film 3 can be formed from a material containing a transition metal and silicon, if an etching selectivity to dry etching can be obtained between the material forming the third layer 23 (esp., surface layer portion). This is because a material containing a transition metal and silicon has high light shielding performance, which enables reduction of thickness of the light shielding film 3. The transition metal to be included in the light shielding film 3 includes one metal among molybdenum (Mo), tantalum (Ta), tungsten (W), titanium (Ti), chromium (Cr), hafnium (Hf), nickel (Ni), vanadium (V), zirconium (Zr), ruthenium (Ru), rhodium (Rh), zinc (Zn), niobium (Nb), palladium (Pd), etc., or an alloy of these metals. Metal elements other than the transition metal elements to be included in the light shielding film 3 include aluminum (Al), indium (In), tin (Sn), gallium (Ga), etc.

On the other hand, as a mask blank 100 of another embodiment, a light shielding film 3 of a structure including a layer of a material including chromium and a layer of a material containing a transition metal and silicon stacked in this order from the phase shift film 2 side can be provided. Concrete matters on the material containing chromium and the material containing a transition metal and silicon in this case are similar to the case of the light shielding film 3 described above.

It is preferable that the mask blank 100 in the state where the phase shift film 2 and the light shielding film 3 are stacked has a back surface reflectance of 9% or less to an exposure light of an ArF excimer laser.

In the mask blank 100, a preferable configuration is that the light shielding film 3 has further stacked thereon a hard mask film 4 formed from a material having etching selectivity to etching gas used in etching the light shielding film 3. Since the hard mask film 4 is basically not limited with regard to optical density, the thickness of the hard mask film 4 can be reduced significantly compared to the thickness of the light shielding film 3. Since a resist film of an organic material only requires a film thickness to function as an etching mask until dry etching for forming a pattern in the hard mask film 4 is completed, the thickness can be reduced significantly compared to conventional resist films. Reduction of film thickness of a resist film is effective for enhancing resist resolution and preventing collapse of pattern, which is extremely important in facing requirements for miniaturization.

In the case where the light shielding film 3 is formed from a material containing chromium, the hard mask film 4 is preferably formed from a material containing silicon. Since the hard mask film 4 in this case tends to have low adhesiveness with a resist film of an organic material, it is preferable to treat the surface of the hard mask film 4 with HMDS (Hexamethyldisilazane) to enhance surface adhesiveness. The hard mask film 4 in this case is more preferably formed from SiO₂, SiN, SiON, etc.

Further, in the case where the light shielding film 3 is formed from a material containing chromium, materials containing tantalum are also applicable as the materials of the hard mask film 4, in addition to the materials given above. The material containing tantalum in this case includes, in addition to tantalum metal, a material containing tantalum and one or more elements selected from nitrogen, oxygen, boron, and carbon, for example, Ta, TaN, TaO, TaON, TaBN, TaBO, TaBON, TaCN, TaCO, TaCON, TaBCN, TaBOCN, etc. Further, in the case where the light shielding film 3 is formed from a material containing silicon, the hard mask film 4 is preferably formed from the material containing chromium given above.

In the mask blank 100, a resist film formed from an organic material is preferably formed at a film thickness of 100 nm or less in contact with a surface of the hard mask film 4. In the case of a fine pattern to meet DRAM hp32nm generation, a SRAF (Sub-Resolution Assist Feature) with 40 nm line width may be provided on a transfer pattern (phase shift pattern) to be formed in the hard mask film 4. However, even in this case, the cross-sectional aspect ratio of the resist pattern can be reduced down to 1:2.5 so that collapse and peeling off of the resist pattern can be prevented in rinsing and developing, etc. of the resist film. Incidentally, the resist film preferably has a film thickness of 80 nm or less.

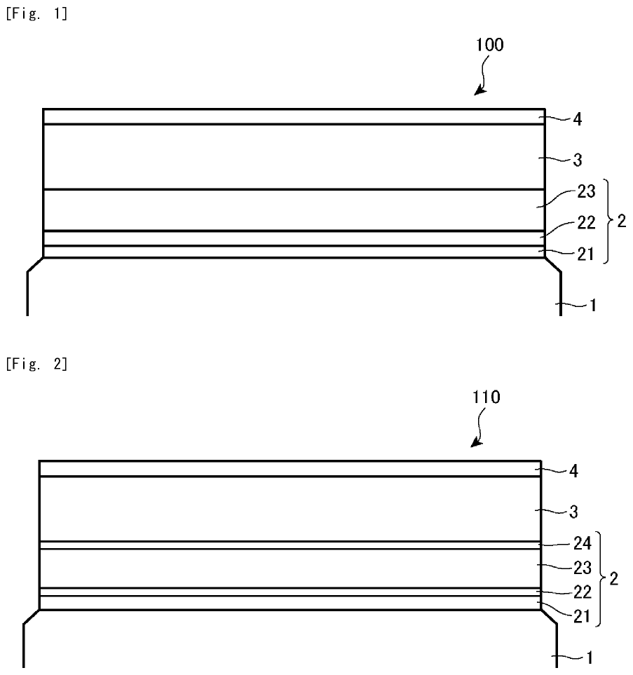

FIG. 2 is a cross-sectional view showing a configuration of a mask blank 110 of the second embodiment of this disclosure. The mask blank 110 of this embodiment has a structure where a first layer 21, a second layer 22, a third layer 23, and a fourth layer 24 are stacked from the transparent substrate 1 side. Preferable refractive indexes, extinction coefficients, and film thicknesses of the first layer 21, the second layer 22, and the third layer 23 are as mentioned in the first embodiment, and their explanations are omitted. Incidentally, the configurations of the transparent substrate 1, the light shielding film 3, and the hard mask film 4 are as mentioned in the first embodiment.

Further, while the fourth layer 24 itself slightly affects a back surface reflectance, it is preferable that a refractive index n₄ of the fourth layer 24 at a wavelength of an exposure light of an ArF excimer laser satisfies the relations of n₁>n₄ and n₃>n₄, and an extinction coefficient k₄ of the fourth layer 24 at a wavelength of an exposure light of an ArF excimer laser satisfies the relations of k₁>k₄ and k₃>k₄. Further, it is preferable to satisfy the relation of n₂>n₄. A refractive index n₄ of the fourth layer 24 is preferably 1.8 or less, and more preferably 1.7 or less. Moreover, a refractive index n₄ of the fourth layer 24 is preferably 1.5 or more, and more preferably 1.55 or more. On the other hand, an extinction coefficient k₄ of the fourth layer 24 is preferably 0.1 or less, and more preferably 0.05 or less.

The fourth layer 24 is preferably formed from a material including silicon and oxygen, or a material including silicon, oxygen, and one or more elements selected from metalloid elements and non-metallic elements. By forming the fourth layer 24 from such materials, generation of haze can be suppressed, which is likely to generate in a silicon-containing film having a large amount of nitrogen content. The thickness of the fourth layer 24 is preferably 15 nm or less, and more preferably 10 nm or less. Further, the thickness of the fourth layer 24 is preferably 1 nm or more, and more preferably 2 nm or more.

FIGS. 3A-3G show a phase shift mask 200, 210 according to the first and second embodiments of this disclosure manufactured from the mask blank 100, 110 of the first and second embodiments, and its manufacturing process. As shown in FIG. 3G, the phase shift mask 200, 210 is featured in that a phase shift pattern 2a as a transfer pattern is formed in the phase shift film 2 of the mask blank 100, 110, and a light shielding pattern 3b is formed in the light shielding film 3. In the case of a configuration where a hard mask film 4 is provided on the mask blank 100, 110, the hard mask film 4 is removed during manufacture of the phase shift mask 200, 210.

The method for manufacturing the phase shift mask 200, 210 of the first and second embodiments of this disclosure uses the mask blank 100, 110 mentioned above, which is featured in including the steps of forming a transfer pattern in the light shielding film 3 by dry etching; forming a transfer pattern in the phase shift film 2 by dry etching with the light shielding film 3 including the transfer pattern as a mask; and forming a light shielding pattern 3b in the light shielding film 3 by dry etching with a resist film 6b including a light shielding pattern as a mask. The method of manufacturing the phase shift mask 200, 210 of this disclosure is explained below according to the manufacturing steps shown in FIGS. 3A-3G. Explained herein is a method of manufacturing the phase shift mask 200, 210 using the mask blank 100, 110 having the hard mask film 4 stacked on the light shielding film 3. Further, a material containing chromium is applied to the light shielding film 3, and a material containing silicon is applied to the hard mask film 4 in this case.

First, a resist film is formed in contact with the hard mask film 4 of the mask blank 100, 110 by spin coating. Next, a first pattern, which is a transfer pattern (phase shift pattern) to be formed in the phase shift film 2, was exposed and written with an electron beam in the resist film, and a predetermined treatment such as developing was conducted, to thereby form a first resist pattern 5a having a phase shift pattern (see FIG. 3A). Subsequently, dry etching was conducted using fluorine-based gas with the first resist pattern 5a as a mask, and a first pattern (hard mask pattern 4a) was formed in the hard mask film 4 (see FIG. 3B).

Next, after removing the resist pattern 5a, dry etching was conducted using mixed gas of chlorine-based gas and oxygen gas with the hard mask pattern 4a as a mask, and a first pattern (light shielding pattern 3a) is formed in the light shielding film 3 (see FIG. 3C). Subsequently, dry etching was conducted using fluorine-based gas with the light shielding pattern 3a as a mask, and a first pattern (phase shift pattern 2a) was formed in the phase shift film 2, and at the same time, the hard mask pattern 4a was removed (see FIG. 3D).

Next, a resist film was formed on the mask blank 100, 110 by spin coating. Next, a second pattern, which is a pattern (light shielding pattern) to be formed in the light shielding film 3, was exposed and written with an electron beam in the resist film, and a predetermined treatment such as developing was conducted, to thereby form a second resist pattern 6b having a light shielding pattern (see FIG. 3E). Subsequently, dry etching was conducted using mixed gas of chlorine-based gas and oxygen gas with the second resist pattern 6b as a mask, and a second pattern (light shielding pattern 3b) was formed in the light shielding film 3 (see FIG. 3F). Further, the second resist pattern 6b was removed, predetermined treatments such as cleaning were carried out, and the phase shift mask 200, 210 was obtained (see FIG. 3G).

There is no particular limitation to chlorine-based gas to be used for the dry etching described above, as long as Cl is included. The chlorine-based gas includes, for example, Cl₂, SiCl₂, CHCl₃, CH₂Cl₂, CCl₄, and BCl₃. Further, there is no particular limitation to fluorine-based gas to be used for the dry etching described above, as long as F is included. The fluorine-based gas includes, for example, CHF₃, CF₄, C₂F₆, C₄F₈, and SF₆. Particularly, fluorine-based gas free of C can further reduce damage on a glass substrate for having a relatively low etching rate to a glass substrate.

The phase shift mask 200, 210 of this disclosure is manufactured using the mask blank 100, 110 mentioned above. Therefore, the phase shift film 2 having a transfer pattern formed therein (phase shift pattern 2a) has a transmittance of 2% or more to an exposure light of an ArF excimer laser, and a phase difference between an exposure light transmitted through the phase shift pattern 2a and the exposure light that transmitted through the air for the same distance as the thickness of the phase shift pattern 2a of within the range of 150 degrees or more and 200 degrees or less. This phase shift mask 200, 210 has 9% or less back surface reflectance in a region of the phase shift pattern 2a where the light shielding pattern 3b is not stacked (region on transparent substrate 1 where only phase shift pattern 2a exists). This can prevent an influence on an exposure transfer image by the stray light when the phase shift mask 200 was used to exposure-transfer an object to be transferred (resist film on semiconductor wafer, etc.).

The method of manufacturing a semiconductor device of this disclosure is featured in using the phase shift mask 200, 210 given above and subjecting a resist film on a semiconductor substrate to exposure-transfer of a transfer pattern. The phase shift mask 200, 210 has both of a function to transmit an exposure light of an ArF excimer laser at a predetermined transmittance and a function to generate a predetermined phase difference to the transmitting exposure light of an ArF excimer laser, and has a back surface reflectance of 9% or less, which is significantly lower than conventional cases. Therefore, even if the phase shift mask 200, 210 was set on an exposure apparatus, and irradiated with an exposure light of an ArF excimer laser from the transparent substrate 1 side of the phase shift mask 200, 210 and exposure-transferred to an object to be transferred (resist film on semiconductor wafer, etc.), projection of bar codes and alignment marks formed on the phase shift mask 200, 210 to the object to be transferred can be suppressed, and a desired pattern can be transferred to the object to be transferred at a high precision.

### EXAMPLES

The embodiments of this disclosure are described in greater detail below together with examples.

### Example 1

### [Manufacture of Mask Blank]

A transparent substrate 1 made from a synthetic quartz glass with a size of a main surface of about 152 mm×about 152 mm and a thickness of about 6.35 mm was prepared. End surfaces and the main surface of the transparent substrate 1 were polished to a predetermined surface roughness, and thereafter subjected to predetermined cleaning treatment and drying treatment. The optical properties of the transparent substrate 1 were measured, and a refractive index n was 1.556 and an extinction coefficient k was 0.00.

Next, a first layer 21 of a phase shift film 2 including silicon and nitrogen (SiN film Si:N=43 atom %:57 atom %) was formed in contact with a surface of the transparent substrate 1 at a thickness of 12 nm. The first layer 21 was formed by placing the transparent substrate 1 in a single-wafer RF sputtering apparatus, and by RF sputtering using a silicon (Si) target, using mixed gas of argon (Ar) and nitrogen (N₂) as sputtering gas. Next, a second layer 22 of the phase shift film 2 including silicon and nitrogen (SiN film Si:N=68 atom %:32 atom %) was formed on the first layer 21 at a thickness of 15 nm. The second layer 22 was formed by reactive sputtering (RF sputtering) using a silicon (Si) target with a mixed gas of argon (Ar) and nitrogen (N₂) as sputtering gas. Next, a third layer 23 of the phase shift film 2 including silicon and nitrogen (SiN film Si:N=43 atom %:57 atom %) was formed on the second layer 22 at a thickness of 42 nm. The third layer 23 was formed by reactive sputtering (RF sputtering) using a silicon (Si) target, with mixed gas of argon (Ar) and nitrogen (N₂) as sputtering gas. By the above procedure, the phase shift film 2 having the first layer 21, the second layer 22, and the third layer 23 stacked in contact with the surface of the transparent substrate 1 was formed at a thickness of 69 nm. The thickness of the third layer 23 of the phase shift film 2 is 3.5 times the thickness of the first layer 21. The composition of the first layer 21, the second layer 22, and the third layer 23 is the result obtained from measurement by X-ray photoelectron spectroscopy (XPS). The same applies to other films hereafter.

Next, a transmittance and a phase difference of the phase shift film 2 to a light of a wavelength (193 nm wavelength) of an exposure light of an ArF excimer laser was measured using a phase shift measurement apparatus (MPM193 manufactured by Lasertec), and a transmittance was 6.2% and a phase difference was 181.8 degrees. Moreover, each optical property was measured for the first layer 21, the second layer 22, and the third layer 23 of the phase shift film 2 using a spectroscopic ellipsometer (M-2000D manufactured by J. A. Woollam), and the first layer 21 had a refractive index n₁ of 2.595 and an extinction coefficient k₁ of 0.357; the second layer 22 had a refractive index n₂ of 1.648 and an extinction coefficient k₂ of 1.861; and the third layer 23 had a refractive index n₃ of 2.595 and an extinction coefficient k₃ of 0.357. A back surface reflectance of the phase shift film 2 to a light of a wavelength of an exposure light of an ArF excimer laser was 3.8%, which was below 9%.

Next, a light shielding film 3 including CrOCN (CrOCN film Cr:O:C:N=55 atom %:22 atom %:12 atom %:11 atom %) was formed on the phase shift film 2 at a thickness of 43 nm. The light shielding film 3 was formed by placing a transparent substrate 1 having the phase shift film 2 formed thereon in a single-wafer DC sputtering apparatus, and by reactive sputtering (DC sputtering) using a chromium (Cr) target with mixed gas of argon (Ar), carbon dioxide (CO₂), nitrogen (N₂), and helium (He) as sputtering gas. A back surface reflectance in the stacked condition of the phase shift film 2 and the light shielding film 3 on the transparent substrate 1 to a light of a wavelength of an exposure light of an ArF excimer laser was 4.7%, which was below 9%. The optical density (OD) to a light of 193 nm wavelength in the stacked structure of the phase shift film 2 and the light shielding film 3 was 3.0 or more. Further, another transparent substrate 1 was prepared, only a light shielding film 3 was formed under the same film-forming conditions, the optical properties of the light shielding film 3 were measured using the spectroscopic ellipsometer, and a refractive index n was 1.92 and an extinction coefficient k was 1.50.

Next, a hard mask film 4 including silicon and oxygen was formed on the light shielding film 3 at a thickness of 5 nm. The hard mask film 4 was formed by placing the transparent substrate 1 having the phase shift film 2 and the light shielding film 3 stacked thereon in a single-wafer RF sputtering apparatus, and by RF sputtering using a silicon dioxide (SiO₂) target with argon (Ar) gas as sputtering gas. Through the above procedure, the mask blank 100 was formed, having the phase shift film 2 of a three layer structure, the light shielding film 3, and the hard mask film 4 are stacked on the transparent substrate 1.

### [Manufacture of Phase Shift Mask]

Next, a phase shift mask 200 of Example 1 was manufactured through the following procedure using the mask blank 100 of Example 1. First, a surface of the hard mask film 4 was subjected to HMDS treatment. Subsequently, a resist film of a chemically amplified resist for electron beam writing was formed in contact with a surface of the hard mask film 4 by spin coating at a film thickness of 80 nm. Next, a first pattern, which is a phase shift pattern to be formed in the phase shift film 2, was written on the resist film by an electron beam. Further, predetermined cleaning and developing treatments were conducted, and a first resist pattern 5a having the first pattern was formed (see FIG. 3A). At this stage, a pattern of a shape corresponding to bar codes and alignment marks was formed in the first resist pattern 5a outside of a pattern forming region.

Next, dry etching using CF₄ gas was conducted with the first resist pattern 5a as a mask, and a first pattern (hard mask pattern 4a) was formed in the hard mask film 4 (see FIG. 3B). At this stage, a pattern of a shape corresponding to bar codes and alignment marks was also formed in the hard mask film 4 outside of a pattern forming region. Thereafter, the first resist pattern 5a was removed.

Subsequently, dry etching was conducted using mixed gas of chlorine and oxygen (gas flow ratio Cl₂:O₂=10:1) with the hard mask pattern 4a as a mask, and a first pattern (light shielding pattern 3a) was formed in the light shielding film 3 (see FIG. 3C). At this stage, a pattern of a shape corresponding to bar codes and alignment marks was also formed in the light shielding film 3 outside of a pattern forming region. Next, dry etching was conducted using fluorine-based gas (SF₆+He) with the light shielding pattern 3a as a mask, and a first pattern (phase shift pattern 2a) was formed in the phase shift film 2, and at the same time the hard mask pattern 4a was removed (see FIG. 3D). At this stage, a pattern of a shape corresponding to bar codes and alignment marks was also formed in the phase shift film 2 outside of a pattern forming region.

Next, a resist film of a chemically amplified resist for electron beam writing was formed on the light shielding pattern 3a by spin coating at a film thickness of 150 nm. Next, a second pattern, which is a pattern to be formed in the light shielding film (light shielding pattern) was exposure-written on the resist film. Moreover, predetermined treatments such as developing were carried out, and a second resist pattern 6b having a light shielding pattern was formed (see FIG. 3E). Subsequently, dry etching was conducted using mixed gas of chlorine and oxygen (gas flow ratio Cl₂:O₂=4:1) with the second resist pattern 6b as a mask, and a second pattern (light shielding pattern 3b) was formed in the light shielding film 3 (see FIG. 3F). Further, the second resist pattern 6b was removed, predetermined treatments such as cleaning were carried out, and the phase shift mask 200 was obtained (see FIG. 3G).

Regarding the phase shift mask 200, a simulation of an exposure transfer image was made when an exposure transfer was made on a resist film on a semiconductor device with an exposure light of an ArF excimer laser, using AIMS193 (manufactured by Carl Zeiss). The exposure transfer image obtained by the simulation was inspected, recognizing that the design specification was fully satisfied. Further, no CD variation was found on the exposure transfer image, which is caused by projection of bar codes and alignment marks. It can be considered from the above that exposure transfer can be made on the resist film on the semiconductor device at a high precision, even if the phase shift mask 200 manufactured from the mask blank of Example 1 was set on an exposure apparatus and subjected to exposure transfer by an exposure light of an ArF excimer laser.

### Example 2

### [Manufacture of Mask Blank]

A mask blank 110 of Example 2 was manufactured through the same procedure as Example 1, except for the phase shift film 2. The changes in the phase shift film 2 of Example 2 are the film thicknesses of the first layer 21, the second layer 22, and the third layer 23; and a fourth layer 24 is formed on the third layer 23. Concretely, the first layer 21 of the phase shift film 2 including silicon and nitrogen (SiN film Si:N=43 atom %:57 atom %) was formed in contact with a surface of the transparent substrate 1 at a thickness of 14 nm. The first layer 21 was formed by placing the transparent substrate 1 in a single-wafer RF sputtering apparatus, and by reactive sputtering (RF sputtering) using a silicon (Si) target, and using mixed gas of argon (Ar) and nitrogen (N₂) as sputtering gas. Next, a second layer 22 of the phase shift film 2 including silicon and nitrogen (SiN film Si:N=68 atom %:32 atom %) was formed on the first layer 21 at a thickness of 8 nm. The second layer 22 was formed by reactive sputtering (RF sputtering) using a silicon (Si) target with mixed gas of argon (Ar) and nitrogen (N₂) as sputtering gas. Next, a third layer 23 of the phase shift film 2 including silicon and nitrogen (SiN film Si:N=43 atom %:57 atom %) was formed on the second layer 22 at a thickness of 43 nm. The third layer 23 was formed by reactive sputtering (RF sputtering) using a silicon (Si) target, with mixed gas of argon (Ar) and nitrogen (N₂) as sputtering gas. Subsequently, a fourth layer 24 of the phase shift film 2 including silicon and oxygen (SiO film Si:O=33 atom %:67 atom %) was formed on the third layer 23 at a thickness of 3 nm. The fourth layer 24 was formed by reactive sputtering (RF sputtering) using a silicon (Si) target with mixed gas of argon (Ar) and oxygen (O₂) as sputtering gas. By the above procedure, the phase shift film 2 having the first layer 21, the second layer 22, the third layer 23, and the fourth layer 24 stacked in contact with the surface of the transparent substrate 1 was formed at a thickness of 68 nm. The thickness of the third layer 23 of the phase shift film 2 is 3.07 times the thickness of the first layer 21.

A transmittance and a phase difference of the phase shift film 2 to a light of a wavelength (193 nm wavelength) of an exposure light of an ArF excimer laser were measured using the phase shift measurement apparatus, and a transmittance was 11.6% and a phase difference was 183.0 degrees. Further, each optical property was measured for the first layer 21, the second layer 22, the third layer 23, and the fourth layer 24 of the phase shift film 2 using the spectroscopic ellipsometer, and the first layer 21 had a refractive index n₁ of 2.595 and an extinction coefficient k₁ of 0.357; the second layer 22 had a refractive index n₂ of 1.648 and an extinction coefficient k₂ of 1.861; the third layer 23 had a refractive index n₃ of 2.595 and an extinction coefficient k₃ of 0.357; and the fourth layer 24 had a refractive index n₄ of 1.590 and an extinction coefficient k₄ of 0.000. A back surface reflectance (reflectance at transparent substrate 1 side) of the phase shift film 2 to a light of a wavelength of an exposure light of an ArF excimer laser was 7.6%, which was below 9%.

Through the above procedure, the mask blank 110 of Example 2 was manufactured, the mask blank 110 having a structure in which the phase shift film 2 including the first layer 21, the second layer 22, the third layer 23, and the fourth layer 24; the light shielding film 3; and the hard mask film 4 are stacked on the transparent substrate 1. In the mask blank 110 of Example 2, a back surface reflectance (reflectance at transparent substrate 1 side) to a light of a wavelength of an exposure light of an ArF excimer laser with the phase shift film 2 and the light shielding film 3 stacked on the transparent substrate 1 was 7.9%, which was below 9%. The optical density (OD) to a light of 193 nm wavelength in the stacked structure of the phase shift film 2 and the light shielding film 3 was 3.0 or more.

### [Manufacture of Phase Shift Mask]

Next, a phase shift mask 210 of Example 2 was manufactured through the same procedure as Example 1 using the mask blank 110 of Example 2.

Regarding the phase shift mask 210, a simulation of an exposure transfer image was made when an exposure transfer was made on a resist film on a semiconductor device with an exposure light of an ArF excimer laser, using AIMS193 (manufactured by Carl Zeiss). The exposure transfer image obtained by the simulation was inspected, recognizing that the design specification was fully satisfied. Further, no CD variation was found on the exposure transfer image, which is caused by projection of bar codes and alignment marks. It can be considered from the above that an exposure transfer can be made on the resist film on the semiconductor device at a high precision, even if the phase shift mask 210 manufactured from the mask blank of Example 2 was set on an exposure apparatus and subjected to exposure transfer by an exposure light of an ArF excimer laser.

### Comparative Example 1

### [Manufacture of Mask Blank]

A mask blank of Comparative Example 1 was manufactured by the same procedure as Example 1, except for a phase shift film. A single layer structure film formed from molybdenum, silicon, and nitrogen was applied for the phase shift film of Comparative Example 1. Concretely, a transparent substrate 1 was placed in a single-wafer DC sputtering apparatus, and by reactive sputtering (DC sputtering) using a mix-sintered target of molybdenum (Mo) and silicon (Si) (Mo:Si=11 atom %:89 atom %) with mixed gas of argon (Ar), nitrogen (N₂), and helium (He) as sputtering gas, a phase shift film formed from molybdenum, silicon, and nitrogen was formed at a thickness of 69 nm.

A transmittance and a phase difference of the phase shift film 2 to a light of an exposure light of an ArF excimer laser were measured using a phase shift measurement apparatus (MPM193 manufactured by Lasertec), and a transmittance was 6.1% and a phase difference was 177.0 degrees. Moreover, the optical properties of the phase shift film were measured with the spectroscopic ellipsometer, and a refractive index n was 2.39, and an extinction coefficient k was 0.57 in a wavelength of an exposure light of an ArF excimer laser. Further, a back surface reflectance (reflectance at transparent substrate 1 side) of the phase shift film to a light of a wavelength of an exposure light of an ArF excimer laser was 13%, significantly exceeding 9%.

By the above procedure, the mask blank of Comparative Example 1 was manufactured, the mask blank having a structure where the phase shift film formed from a single layer structure of MoSiN, the light shielding film, and the hard mask film are stacked on the transparent substrate. In the mask blank of Comparative Example 1, a back surface reflectance to an exposure light of an ArF excimer laser with the phase shift film and the light shielding film stacked on the transparent substrate was 11.0%, significantly exceeding 9%.

### [Manufacture of Phase Shift Mask]

Next, using the mask blank of Comparative Example 1, a phase shift mask of Comparative Example 1 was manufactured through the same procedure as Example 1.

Regarding the half tone phase shift mask of Comparative Example 1 manufactured, a simulation of an exposure transfer image was made when an exposure transfer was made on a resist film on a semiconductor device with an exposure light of an ArF excimer laser, using AIMS193 (manufactured by Carl Zeiss). The exposure transfer image obtained by this simulation was inspected, and CD variation caused by projection of bar codes and alignment marks was observed, which did not satisfy the design specification. It can be considered from this result that a highly precise exposure transfer cannot be made on a resist film on a semiconductor device with the phase shift mask manufactured from the mask blank of Comparative Example 1.

### Comparative Example 2

### [Manufacture of Mask Blank]

A mask blank of Comparative Example 2 was manufactured by the same procedure as Example 1, except for a phase shift film. In the phase shift film of Comparative Example 2, the film thicknesses of the first layer, the second layer, and the third layer are changed to 32 nm, 10 nm, and 25 nm, respectively. The phase shift film has the third layer having a thickness that is 0.78 times the thickness of the first layer, which is below two times the thickness. A refractive index and an extinction coefficient of each of the first layer, the second layer, and the third layer of the phase shift film 2 are similar to those of Example 1.

The phase shift film had a phase difference of 178.4 degrees and a transmittance of 6.5%. For an optical density (OD) of the stacked structure of the phase shift film and the light shielding film to a light of a wavelength (193 nm) of an exposure light of an ArF excimer laser to be 3.0 or more, composition and optical properties of the light shielding film were kept unchanged from Example 1, but the thickness was changed to 46 nm. A back surface reflectance of the phase shift film to an exposure light of an Arf excimer laser was 35.1%, significantly exceeding 9%.

Through the above procedures, the mask blank of Comparative Example 2 having a structure where the phase shift film, the light shielding film, and the hard mask film are stacked on the transparent substrate was manufactured. In the mask blank of Comparative Example 2, a back surface reflectance to an exposure light of an ArF excimer laser with the phase shift film and the light shielding film stacked on the transparent substrate was 34.9%, significantly exceeding 9%.

### [Manufacture of Phase Shift Mask]

Next, a phase shift mask of Comparative Example 2 was manufactured through the same procedure as Example 1 using the mask blank of Comparative Example 2.

Regarding the half tone phase shift mask of Comparative Example 2 manufactured, a simulation of an exposure transfer image was made when an exposure transfer was made on a resist film on a semiconductor device with an exposure light of an ArF excimer laser, using AIMS193 (manufactured by Carl Zeiss). The exposure transfer image obtained by this simulation was inspected, and CD variation caused by projection of bar codes and alignment marks was observed, which did not satisfy the design specification. It can be considered from this result that a highly precise exposure transfer cannot be made on a resist film on a semiconductor device with the phase shift mask manufactured from the mask blank of Comparative Example 2.

### DESCRIPTION OF REFERENCE NUMERALS

1 transparent substrate
2 phase shift film
21 first layer
22 second layer
23 third layer
24 fourth layer
2a phase shift pattern
3 light shielding film
3a, 3b light shielding pattern
4 hard mask film
4a hard mask pattern
5a first resist pattern
6b second resist pattern
100, 110 mask blank
200, 210 phase shift mask

1. A mask blank comprising a phase shift film on a transparent substrate,
wherein the phase shift film comprises a first layer having a film thickness d1, a second layer having a film thickness d2, and a third layer having a film thickness d3 which is greater than d1 and is greater than d2, and
wherein among the first, second, and third layers, the first layer is closest to the transparent substrate, the third layer is farthest from the transparent substrate, and the second layer is between the first layer and the third layer, and
wherein, at a wavelength of 193 nm:
the first layer has a refractive index n1 and an extinction coefficient k1,
the third layer has a refractive index n3 and an extinction coefficient k3,
the second layer has a refractive index n2 which is less than n1 and is less than n3, and
the second layer has an extinction coefficient k2 which is greater than k1 and is greater than k3.

2. The mask blank according to claim 1, wherein the film thickness d3 of the third layer is two times or more than the film thickness d1 of the first layer.

3. The mask blank according to claim 1, wherein the film thickness d2 of the second layer is 20 nm or less.

4. The mask blank according to claim 1, wherein the refractive index n1 of the first layer is 2.0 or more, the extinction coefficient k1 of the first layer is 0.5 or less, the refractive index n2 of the second layer is less than 2.0, the extinction coefficient k2 of the second layer is 1.0 or more, the refractive index n3 of the third layer is 2.0 or more, and the extinction coefficient k3 of the third layer is 0.5 or less.

5. The mask blank according to claim 1, wherein a transmittance of the phase shift film with respect to a light having a wavelength of 193 nm is 2% or more, and
wherein the phase shift film is configured to transmit the light so that the transmitted light has a phase difference of 150 degrees or more and 200 degrees or less with respect to the light transmitted through air for a same distance as a thickness of the phase shift film.

6. The mask blank according to claim 1, wherein the first layer is provided in contact with a surface of the transparent substrate.

7. The mask blank according to claim 1, wherein the first layer, the second layer, and the third layer contain silicon and nitrogen.

8. The mask blank according to claim 7, wherein a nitrogen content of the second layer is less than a nitrogen content of the first layer and is less than a nitrogen content of the third layer.

9. The mask blank according to claim 1,
wherein the phase shift film comprises a fourth layer on the third layer,
wherein a refractive index n4 of the fourth layer at the wavelength of 193 nm is less than the refractive index n1 of the first layer and is less than the refractive index n3 of the third layer, and
wherein an extinction coefficient k4 of the fourth layer at the wavelength of 193 nm is less than the extinction coefficient k1 of the first layer and is less than the extinction coefficient k3 of the third layer.

10. The mask blank according to claim 9, wherein the refractive index n4 of the fourth layer is 1.8 or less and the extinction coefficient k4 of the fourth layer is 0.1 or less.

11. The mask blank according to claim 9, wherein the fourth layer contains silicon and oxygen.

12. A phase shift mask comprising a phase shift film having a transfer pattern on a transparent substrate,
wherein the phase shift film comprises a first layer having a film thickness d1, a second layer having a film thickness d2, and a third layer having a film thickness d3 which is greater than d1 and is greater than d2, and
wherein among the first, second, and third layers, the first layer is closest to the transparent substrate, the third layer is farthest from the transparent substrate, and the second layer is between the first layer and the third layer, and
wherein, at a wavelength of 193 nm:
the first layer has a refractive index n1 and an extinction coefficient k1,
the third layer has a refractive index n3 and an extinction coefficient k3,
the second layer has a refractive index n2 which is less than n1 and is less than n3, and
the second layer has an extinction coefficient k2 which is greater than k1 and is greater than k3.

13. The phase shift mask according to claim 12, wherein the film thickness d3 of the third layer is two times or more than the film thickness d1 of the first layer.

14. The phase shift mask according to claim 12, wherein the film thickness d2 of the second layer is 20 nm or less.

15. The phase shift mask according to claim 12, wherein the refractive index n1 of the first layer is 2.0 or more, the extinction coefficient k1 of the first layer is 0.5 or less, the refractive index n2 of the second layer is less than 2.0, the extinction coefficient k2 of the second layer is 1.0 or more, the refractive index n3 of the third layer is 2.0 or more, and the extinction coefficient k3 of the third layer is 0.5 or less.

16. A phase shift mask according to claim 12, wherein a transmittance of the phase shift film with respect to a light having a wavelength of 193 nm is 2% or more, and
wherein the phase shift film is configured to transmit the light so that the transmitted light has a phase difference of 150 degrees or more and 200 degrees or less with respect to the light transmitted through air for a same distance as a thickness of the phase shift film.

17. The phase shift mask according to claim 12, wherein the first layer is provided in contact with a surface of the transparent substrate.

18. The phase shift mask according to claim 12, wherein the first layer, the second layer, and the third layer contain silicon and nitrogen.

19. The phase shift mask according to claim 18, wherein a nitrogen content of the second layer is less than a nitrogen content of the first layer and is less than a nitrogen content of the third layer.

20. The phase shift mask according to claim 12,
wherein a refractive index n4 of the fourth layer at the wavelength of 193 nm is less than the refractive index n1 of the first layer and is less than the refractive index n3 of the third layer, and
wherein an extinction coefficient k4 of the fourth layer at the wavelength of 193 nm is less than the extinction coefficient k1 of the first layer and is less than the extinction coefficient k3 of the third layer.

21. The phase shift mask according to claim 20, wherein the refractive index n4 of the fourth layer is 1.8 or less and the extinction coefficient k4 of the fourth layer is 0.1 or less.

22. The phase shift mask according to claim 20, wherein the fourth layer contains silicon and oxygen.

23. A method of manufacturing a semiconductor device comprising using the phase shift mask according to claim 12 to exposure-transfer a transfer pattern to a resist film on a semiconductor substrate.
